(19) United States
(12) Patent Application Publication
(10) Pub. No.: US 2013/0125960 A1
(43) Pub. Date: May 23, 2013

(54) PHOTOELECTRIC CONVERSION DEVICE

(71) Applicants: Nam-Choul Yang, Yongin-si (KR); Do-Young Park, Yongin-si (KR); Sang-Hyuck Ahn, Yongin-si (KR)

(72) Inventors: Nam-Choul Yang, Yongin-si (KR); Do-Young Park, Yongin-si (KR); Sang-Hyuck Ahn, Yongin-si (KR)

(73) Assignee: Samsung SDI Co., Ltd., Yongin-si (KR)

(21) Appl. No.: 13/455,850

(22) Filed: Apr. 25, 2012

(30) Foreign Application Priority Data
Nov. 18, 2011 (KR) 10-2011-0121190

(51) Int. Cl. H01L 31/02

(52) U.S. Cl. 136/252

(57) ABSTRACT

A photoelectric conversion device configured to contain an electrolyte is disclosed. In one embodiment, the device includes first and second substrates facing each other, wherein first and second electrodes are formed on the first and second substrates, respectively, and an electrolyte inlet formed to pass through at least one of the first and second substrates. The device may further include a sealing member formed on an external surface of the first substrate to cover an entrance of the electrolyte inlet, wherein the sealing member comprises i) an inner area which is located substantially directly above the entrance of the electrolyte inlet and ii) at least one energy application area onto which energy is directly or indirectly applied, and wherein the energy application area extends outwardly from the inner area so as not to overlap with the entrance of the electrolyte inlet.

### RELATED APPLICATIONS

This application claims the benefit of Korean Patent Application No. 10-2011-0121190, filed on Nov. 18, 2011, in the Korean Intellectual Property Office, the disclosure of which is incorporated herein in its entirety by reference.

### BACKGROUND

1. Field

The described technology generally relates to a photoelectric conversion device, and more particularly, to a photoelectric conversion device with high sealing performance of an electrolyte inlet.

2. Description of the Related Technology

Extensive research has recently been conducted on photoelectric conversion devices that convert light into electric energy. From among such devices, solar cells utilizing sunlight have attracted attention as alternative energy sources to fossil fuels.

Though research on various solar cells having various working principles has been continuously conducted, wafer-based crystalline silicon solar cells using a p-n semiconductor junction have appeared to be the most prevalent solar cells. However, the manufacturing costs of wafer-based crystalline silicon solar cells are high because they are formed of a high purity semiconductor material.

Unlike silicon solar cells, dye-sensitized solar cells include i) a photosensitive dye that receives visible light and generates excited electrons, ii) a semiconductor material that receives the excited electrons, and iii) an electrolyte that reacts with electrons returning from an external circuit. Since dye-sensitized solar cells have much higher photoelectric conversion efficiency than other solar cells, they are viewed as next generation solar cells.

### SUMMARY

One inventive aspect is a photoelectric conversion device with high sealing performance of an electrolyte inlet.

Another aspect is a photoelectric conversion device which includes a first substrate and a second substrate on which a first electrode and a second electrode are respectively formed, facing each other; an electrolyte that is injected via an electrolyte inlet formed through the first substrate and filled between the first and second substrates; and a sealing member fused on a portion of the first substrate around the electrolyte inlet and including laser irradiation areas formed on edge portions that deviate from a viewing area of the electrolyte inlet.

The laser irradiation areas may correspond to step portions of the sealing member.

The step portions may each be lowered downward on two sides of the sealing member with respect to the viewing area of the electrolyte inlet.

The step portions may each have a concave shape on two sides of the sealing member with respect to the viewing area of the electrolyte inlet.

The sealing member may include a cover member for covering the electrolyte inlet; an interlayer sealing member disposed on the cover member; and an external sealing member disposed on the interlayer sealing member.

Each of the cover member and the interlayer sealing member may include a hot-melt resin, and the external sealing member may include a metal-based material.

The external sealing member may include a titanium thin film.

The sealing member may include a glass frit formed to surround the electrolyte inlet on the portion of the first substrate around the electrolyte inlet; and an external sealing member formed on the glass frit.

The laser irradiation areas may correspond to laser fusing portions of the glass frit.

The external sealing member may include a titanium thin film.

Another aspect is a photoelectric conversion device which includes a first substrate and a second substrate on which a first electrode and a second electrode are respectively formed, facing each other; an electrolyte that is injected via an electrolyte inlet formed through the first substrate and filled between the first and second substrates; and a sealing member fused on a portion of the first substrate around the electrolyte inlet and including step portions formed on edge portions that deviate from a viewing area of the electrolyte inlet.

The step portions may each be lowered downward on two sides of the sealing member with respect to the viewing area of the electrolyte inlet.

The step portions may each have a concave shape on two sides of the sealing member with respect to the viewing area of the electrolyte inlet.

Another aspect is a photoelectric conversion device which includes a first substrate and a second substrate on which a first electrode and a second electrode are respectively formed, facing each other; an electrolyte that is injected via an electrolyte inlet formed through the first substrate and filled between the first and second substrates; a glass frit formed to surround the electrolyte inlet on a portion of the first substrate around the electrolyte inlet; and an external sealing member disposed on the glass frit and fused on the glass frit.

The glass frit may be formed to surround an end edge portion of the external sealing member.

The glass frit may be formed to deviate from the external sealing member and to extend to right and left sides with respect to the viewing area of the electrolyte inlet surround.

The external sealing member may include a titanium thin film. Another aspect is a photoelectric conversion device configured to contain an electrolyte, the device comprising: first and second substrates facing each other, wherein first and second electrodes are formed on the first and second substrates, respectively; an electrolyte inlet formed to pass through at least one of the first and second substrates; and a sealing member formed on an external surface of the first substrate to cover an entrance of the electrolyte inlet, wherein the sealing member comprises i) an inner area which is located substantially directly above the entrance of the electrolyte inlet and ii) at least one energy application area onto which energy is directly or indirectly applied, and wherein the energy application area extends outwardly from the inner area so as not to overlap with the entrance of the electrolyte inlet.

In the above device, the energy application area has at least one non-linear portion. In the above device, at least part of the non-linear portion extends in an inclined direction toward the first substrate. In the above device, the non-linear portion is concave toward the first substrate. In the above device, the sealing member comprises: a cover member configured to cover the entrance of the electrolyte inlet; an interlayer sealing member disposed on the cover member; and an external sealing member disposed on the interlayer sealing member. In the above device, each of the cover member and the interlayer sealing member is formed of a hot-melt resin, and wherein the external sealing member is formed of a metal-based material.

In the above device, the external sealing member comprises a titanium thin film. In the above device, a glass frit is formed between the sealing member and external surface of the first substrate. In the above device, the energy application area is located substantially directly above the glass frit. In the above device, the sealing member comprises a titanium thin film. In the above device, the energy application area is configured to receive a laser beam so as to fuse the sealing member onto the first substrate.

Another aspect is a photoelectric conversion device configured to contain an electrolyte, the device comprising: first and second substrates facing each other, wherein first and second electrodes are formed on the first and second substrates, respectively; an electrolyte inlet formed to pass through at least one of the first and second substrates; and a sealing member formed on an external surface of the first substrate so as to surround an entrance of the electrolyte inlet, wherein the sealing member has a non-linear portion at least part of which extends in an inclined direction, and wherein the non-linear portion of the sealing member is not aligned with the entrance of the electrolyte inlet in a direction in which the electrolyte inlet extends.

In the above device, at least part of the non-linear portion is concave toward the first substrate. In the above device, the non-linear portion is configured to receive a laser beam so as to fuse the sealing member onto the first substrate. In the above device, the non-linear portion is not located directly above the entrance of the electrolyte inlet.

Another aspect is a photoelectric conversion device configured to contain an electrolyte, the device comprising: first and second substrates facing each other, wherein first and second electrodes are formed on the first and second substrates, respectively; an electrolyte inlet formed to pass through at least one of the first and second substrates; and a sealing member formed on an external surface of the at least one substrate via a glass frit so as to surround an entrance of the electrolyte inlet.

In the above device, the glass frit does not overlap with the electrolyte inlet. In the above device, the glass frit extends outwardly from the entrance of the electrode inlet beyond the perimeter of the sealing member. In the above device, the sealing member comprises a titanium thin film. In the above device, the sealing member does not directly contact the external surface of the at least one substrate.

### BRIEF DESCRIPTION OF THE DRAWINGS

FIG. 1 is an exploded perspective view of a photoelectric conversion device according to an embodiment.

FIG. 2 is a cross-sectional view of the photoelectric conversion device taken along a line II-II of FIG. 1 according to an embodiment.

FIG. 3 is a cross-sectional view of the photoelectric conversion device taken along a line III-III of FIG. 1 according to an embodiment.

FIG. 4 is an enlarged cross-sectional view of a sealing structure of an electrolyte inlet of FIG. 3 according to an embodiment.

FIG. 5 is a cross-sectional view for describing a sealing operation of the electrolyte inlet shown in FIG. 4 according to an embodiment.

FIG. 6 is a cross-sectional view for describing a sealing structure of an electrolyte inlet according to a comparative example.

FIG. 7 is a cross-sectional view for describing a sealing structure of an electrolyte inlet according to another embodiment.

FIG. 8 is an enlarged cross-sectional view of the sealing structure of the electrolyte inlet of FIG. 7 according to another embodiment.

FIG. 9 is a cross-sectional view for describing a sealing operation of the electrolyte inlet shown in FIG. 8 according to another embodiment.

FIG. 10 is a cross-sectional view for describing a sealing structure of an electrolyte inlet according to another embodiment.

FIG. 11 is an enlarged cross-sectional view of the sealing structure of the electrolyte inlet of FIG. 10 according to another embodiment.

FIGS. 12 and 13 are cross-sectional views for describing a sealing operation of the electrolyte inlet shown in FIG. 11 according to another embodiment.

FIGS. 14A through 14H are cross-sectional views sequentially illustrating a method of manufacturing a photoelectric conversion device according to an embodiment.

### DETAILED DESCRIPTION

Embodiments will be described with reference to the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects of the present description.

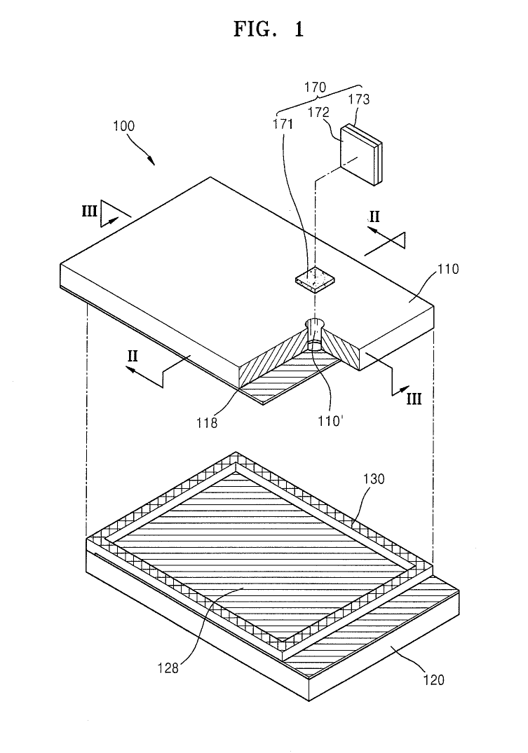

FIG. 1 is an exploded perspective view of a photoelectric conversion device 100 according to an embodiment. Referring to FIG. 1, the photoelectric conversion device 100 includes i) first and second substrates 110 and 120, ii) function layers 118 and 128, iii) a sealing member 130 and iv) an electrolyte inlet 110′. The function layers 118 and 128, which perform photoelectric conversion, are respectively formed on the first and second substrates 110 and 120 so as to face each other. The sealing member 130 is formed along edges of the substrates 110 and 120 so as to seal the space between the two substrates 110 and 120. The electrolyte inlet 110′ passes through the first substrate 110, and an electrolyte (not shown) is injected into the photoelectric conversion device 100 via the electrolyte inlet 110′.

In one embodiment, as shown in FIG. 1, the electrolyte inlet 110′ is illustrated as being formed in the first substrate 110, which is a light-receiving substrate, but it is not limited to the above example. For example, the electrolyte inlet 110′ may be formed through the second substrate 120, which is a counter substrate. The electrolyte inlet 110′ may also be formed to pass through at least one of the first and second substrates 110 and 120. For the purpose of convenience, the electrolyte inlet 110′ formed in the first substrate 110 will be described.

The electrolyte injected into the photoelectric conversion device 100 is sealed by the sealing member 130 so that the electrolyte does not leak to the outside of the device 100. At least one of the function layers 118 and 128, which are respectively formed on the first and second substrates 110 and 120, includes a semiconductor layer for generating electrons which are excited by irradiated light and electrodes for collecting and discharging the generated electrons. For example, an end of the electrodes constituting the function layers 118 and 128 may extend outside the sealing member 130 to be electrically connected with an external circuit (not shown).

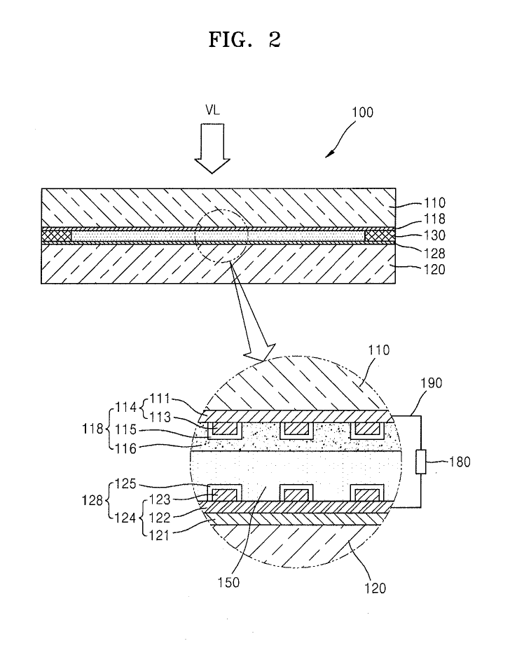

FIG. 2 is a cross-sectional view of the photoelectric conversion device 100 taken along a line II-II of FIG. 1 according to an embodiment. Referring to FIG. 2, the device 100 includes a photoelectrode 114 formed on the first substrate 110 and a counter electrode 124 formed on the second substrate 120 which face each other. The device 100 also includes i) a semiconductor layer 116 which is formed on the photoelectrode 114 (or on a protective layer 115) and ii) an electrolyte 150 disposed between the semiconductor layer 116 and the counter electrode 124. A photosensitive dye, which has been adsorbed into the semiconductor layer 116, is excited by light VL. An electrolyte 150 is substantially filled between the semiconductor layer 116 and the counter electrode 124. For example, the photoelectrode 114 and the semiconductor layer 116 constitute the function layer 118 of the first substrate 110, and the counter electrode 124 constitutes the function layer 128 of the second substrate 120.

The first and second substrates 110 and 120 are attached to each other at a predetermined interval from each other with the sealing member 130 therebetween, and the electrolyte 150 is filled between the substrates 110 and 120. The sealing member 130 surrounds the electrolyte 150 to contain the electrolyte 150, and the electrolyte 150 is sealed by the sealing member 130 so as to prevent the electrolyte 150 from leaking out of the photoelectric conversion device 100.

The photoelectrode 114 and the counter electrode 124 are electrically connected to each other via a conductive wire 190 through an external circuit 180. In a module in which a plurality of photoelectric conversion devices are connected in series or in parallel. Photoelectrodes and counter electrodes 114 and 124 of the photoelectric conversion devices may be connected in series or in parallel. Furthermore, photoelectric conversion devices at ends of the connected photoelectric conversion devices may be connected to the external circuit 180.

The first substrate 110 may be formed of a transparent material having a high light transmittance. For example, the first substrate 110 may be a glass substrate or a resin film substrate. Since a resin film usually has flexibility, a resin film may be applied to devices requiring flexibility.

The photoelectrode 114 may include a transparent conductive layer 111 and a grid electrode 113 in a mesh pattern that is formed on the transparent conductive layer 111. The transparent conductive layer 111 may be formed of a material having transparency and electrical conductivity, for example, a transparent conducting oxide (TCO) such as indium tin oxide (ITO), fluorine tin oxide (FTO), or antimony tin oxide (ATO). The grid electrode 113 is used to reduce the electrical resistance of the photoelectrode 114 and functions as a collector wire that collects electrons generated by photoelectric conversion and provides a low resistance current path. For example, the grid electrode 113 may be formed of a metal material having high electrical conductivity, such as gold (Ag), silver (Au), or aluminium (Al), and may be patterned into a mesh.

The photoelectrode 114 may function as a negative electrode of the photoelectric conversion device 100 and may have a high aperture ratio. Since the light VL incident through the photoelectrode 114 excites a photosensitive dye adsorbed on the semiconductor layer 116, the photoelectric conversion efficiency thereof may be improved when the amount of the incident light VL is increased.

A protective layer 115 may be further formed on an outer surface of the grid electrode 113. The protective layer 115 prevents the grid electrode 113 from being damaged, for example, from eroding, by preventing the grid electrode 113 from contacting and reacting with the electrolyte 150. The protective layer 115 may be formed of a material that does not generally react with the electrolyte 150, for example, a curable resin material.

The semiconductor layer 116 may be formed of a semiconductor material that is usually used in a general photoelectric conversion device, for example, an oxide of a metal selected from cadmium (Cd), zinc (Zn), indium (In), plumbum (Pb), molybdenum (Mo), tungsten (W), stibium (Sb), titanium (Ti), silver (Ag), manganese (Mn), stannum (Sn), zirconium (Zr), strontium (Sr), gallium (Ga), silicon (Si), and chromium (Cr). The semiconductor layer 116 may improve the photoelectric conversion efficiency thereof by adsorbing the photosensitive dye. For example, the semiconductor layer 116 may be formed by coating a paste of semiconductor particles having a particle diameter of about 5 nm to about 1000 nm on the first substrate 110 on which the photoelectrode 114 is formed and applying heat or pressure to the resultant structure.

The photosensitive dye adsorbed in the semiconductor layer 116 may absorb the light VL passing through the first substrate 110, and when the light VL is absorbed by the photosensitive dye, electrons of the photosensitive dye are excited from a ground state. The excited electrons are transferred to the conduction band of the semiconductor layer 116 through electrical contact between the semiconductor layer 116 and the photosensitive dye, and then transferred to the photoelectrode 114, from which the electrons are discharged out of the photoelectric conversion device 100, thereby forming a driving current for driving the external circuit 180.

For example, the photosensitive dye adsorbed in the semiconductor layer 116 may include molecules from which electrons excited by absorbing visible light are rapidly moved to the semiconductor layer 116. The photosensitive dye may be a liquid type, semi-solid gel type, or solid type photosensitive dye. For example, the photosensitive dye adsorbed on the semiconductor layer 116 may be a ruthenium-based photosensitive dye. The semiconductor layer 116 on which the photosensitive dye is adsorbed may be obtained by dipping the first substrate 110 on which the semiconductor layer 116 is formed in a solution containing a predetermined photosensitive dye.

The electrolyte 150 may be a redox electrolyte containing reduced/oxidized (R/O) couples. The electrolyte 150 may be a solid type, gel type, or liquid type electrolyte.

In one embodiment, the second substrate 120 is not transparent. In another embodiment, in order to improve the photoelectric conversion efficiency of the photoelectric conversion device 100, the second substrate 120 may be formed of a transparent material so that the light VL may pass through both sides of the photoelectric conversion device 100 and may be formed of the same material as that of the first substrate 110. In particular, if the photoelectric conversion device 100 is installed as a building integrated photovoltaic (BIPV) system in a structure, e.g., a window frame, both sides of the photoelectric conversion device 100 may be transparent so that the light VL may be introduced into a building and not blocked.

The counter electrode 124 may include a transparent conductive layer 121 and a catalyst layer 122 formed on the transparent conductive layer 121. The transparent conductive layer 121 may be formed of a material having transparency and electrical conductivity, for example, a TCO such as ITO, FTO, or ATO. The catalyst layer 122 may be formed of a reduction catalyzing material for providing electrons to the electrolyte 150, for example, a metal such as platinum (Pt), gold (Ag), silver (Au), copper (Cu), or aluminum (Al), a metal oxide such as tin oxide, or a carbonaceous material such as graphite.

The counter electrode 124 functions as a positive electrode of the photoelectric conversion device 100 and also as a reduction catalyst for providing electrons to the electrolyte 150. When the photosensitive dye adsorbed in the semiconductor layer 116 absorbs the light VL, electrons are excited and discharged out of the photoelectric conversion device 100 through the photoelectrode 114. The photosensitive dye having lost electrons is reduced again by receiving electrons generated by oxidization of the electrolyte 150. Furthermore, the oxidized electrolyte 150 is reduced again by electrons passing through the external circuit 180 and reaching the counter electrode 124, thereby completing an operation of the photoelectric conversion device 100.

The counter electrode 124 may include a grid electrode 123. The grid electrode 123 may be formed on the catalyst layer 122. The grid electrode 123 is used to reduce the electrical resistance of the counter electrode 124 and provides a low resistance current path for collecting electrons reaching the counter electrode 124 via the external circuit 180 and providing the electrons to the electrolyte 150. For example, the grid electrode 123 may be formed of a metal material having high electrical conductivity, such as Ag, Au, or Al, and may be patterned into a mesh.

A protective layer 125 may be further formed on an outer surface of the grid electrode 123. The protective layer 125 prevents the grid electrode 123 from being damaged, for example, from eroding, by preventing the grid electrode 123 from contacting and reacting with the electrolyte 150. The protective layer 125 may be formed of a material that does not generally react with the electrolyte 150, for example, a curable resin material.

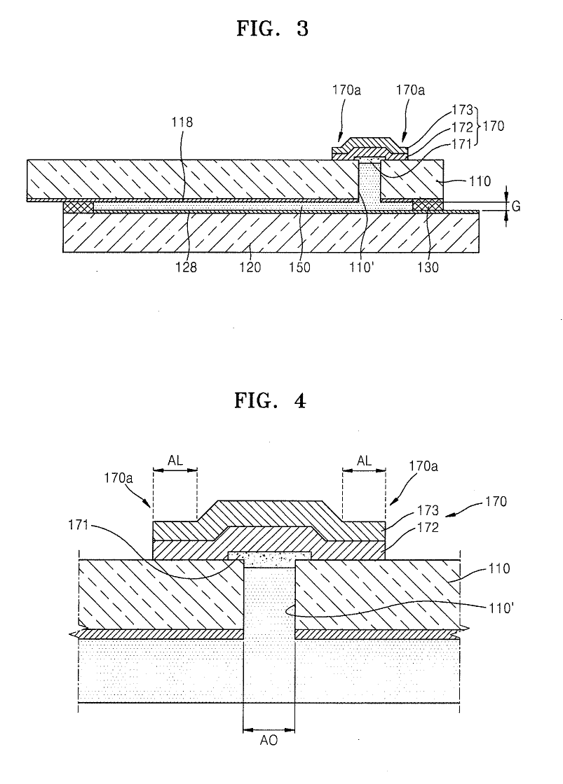

FIG. 3 is a cross-sectional view of the photoelectric conversion device 100 taken along a line III-III of FIG. 1 according to an embodiment. FIG. 4 is an enlarged cross-sectional view of a sealing structure of the electrolyte inlet 110′ of FIG. 3 according to an embodiment. Referring to FIGS. 3 and 4, a substrate gap G with an appropriate size is formed between the first and second substrates 110 and 120 by the sealing member 130 interposed between the two substrates 110 and 120 and applied along the edges of the substrates 110 and 120. Furthermore, predetermined pressure and heat are applied to the substrates 110 and 120 to attach the first substrate 110 to the second substrate 120. The substrate gap G is substantially filled with the electrolyte 150. For example, the electrolyte inlet 110′ for providing an inlet path of the electrolyte 150 is formed through the first substrate 110. The electrolyte inlet 110′ is formed so as to pass through the first substrate 110 and connected to the substrate gap G. For example, the electrolyte inlet 110′ may have a substantially cylindrical shape.

The electrolyte inlet 110′ is sealed by an inlet sealing member 170. The inlet sealing member 170 includes a cover member 171 that directly covers and shields the electrolyte inlet 110′, and an external sealing member 173 that is an outermost member disposed on the cover member 171. An interlayer sealing member 172 may be interposed between the cover member 171 and the external sealing member 173.

The cover member 171 directly covers the electrolyte inlet 110′ and shields the electrolyte inlet 110′. The external sealing member 173 is disposed on the cover member 171 covering the electrolyte inlet 110′ so as to reinforce sealing characteristics. As shown in FIG. 3, step portions 170a each having a step difference that is lowered downward may be formed on two edges of the inlet sealing member 170. The step portions 170a may respectively correspond to laser irradiation areas AL to which a laser beam as an external light source is irradiated for fusing the inlet sealing member 170 when the electrolyte inlet 110′ is sealed by using the inlet sealing member 170.

The cover member 171, the interlayer sealing member 172, and the external sealing member 173 constitute a multiple-sealing structure so as to seal the electrolyte inlet 110′ by using a triple sealing structure. For example, the cover member 171 constitutes a first sealing structure for directly shielding the electrolyte inlet 110′. The interlayer sealing member 172 constitutes a second sealing structure disposed on the cover member 171. The external sealing member 173 constitutes a third sealing structure disposed on the interlayer sealing member 172. However, the present embodiment is not limited to the above sealing structure. For example, the inlet sealing member 170 may include only i) the cover member 171 for directly shielding the electrolyte inlet 110′ and ii) the external sealing member 173.

The cover member 171 covers a surrounding portion of the electrolyte inlet 110′ so as to prevent the electrolyte 150 substantially filled in the substrate gap G from leaking on the first substrate 110 via a fusing portion between the inlet sealing member 170 and the first substrate 110 or contaminating the fusing portion, prior to laser fusing of the inlet sealing member 170. The cover member 171 may perform temporary sealing prior to permanent sealing via, for example, laser fusing. In another embodiment,

In addition, the cover member 171 may prevent the electrolyte 150 from being contaminated by external impurities such as moisture or humidity prior to laser fusing. The cover member 171 may be formed over a relatively narrow area of the first substrate 110 so as to cover the electrolyte inlet 110′. The interlayer sealing member 172 may be attached to an area of the first substrate 110 not covered by the cover member 171, as will be described later. The cover member 171 directly contacts the electrolyte 150 and thus may be formed of a material that does not chemically react with the electrolyte 150 and may be formed of a resin material that is capable of closely contacting the electrolyte inlet 110′, such as a hot melt resin.

The interlayer sealing member 172 may be disposed on an upper portion and edge portions of the cover member 171 to directly cover and protect the electrolyte inlet 110′ and may be fused onto the cover member 171 and a portion of the first substrate 110 exposed around the cover member 171, by laser fusing.

In one embodiment, the interlayer sealing member 172 is formed of a resin-based component that may be transited to a melting state, a semi melting state, or a near melting state to be fused onto the first substrate 110, and in particular, may be formed of a hot melt resin or the like that varies according to a temperature environment. The interlayer sealing member 172 may be closely attached to the first substrate 110 so as to effectively prevent leakage of the electrolyte 150 or penetration of external impurities.

The interlayer sealing member 172 may be interposed between the external sealing member 173 and the first substrate 110 and may serve as a medium for coupling the external sealing member 173 to the first substrate 110. The interlayer sealing member 172 may have a sufficient width to prevent the electrolyte 150 from leaking and may be formed over a relatively wide area including the electrolyte inlet 110′ so as to prevent leakage of the electrolyte 150 and penetration of external impurities.

For example, the cover member 171 and the interlayer sealing member 172 may be formed of a hot-melt resin and may include ethylvinylacetate, polyolefin, silicon, ionomer, and a modified resin-based material thereof. Depending on the embodiment, the modified resin-based material may be impregnated with an inorganic filter such as SiO₂, Al₂O₃, and TiO₂.

The external sealing member 173 corresponds to an outermost layer of the inlet sealing member 170 and may prevent external impurities from penetrating into the electrolyte 150. For example, the external sealing member 173 may be formed of a non-resin based material having excellent shielding properties with respect to moisture or humidity. In addition, the external sealing member 173 may be formed of a conductive material that spreads heat generated by laser irradiation in a thickness direction so as to apply melting heat of the interlayer sealing member 172.

As a result, the external sealing member 173 may be formed of a metal-based material that has excellent shielding properties with respect to external moisture such as moisture or humidity and has thermal conductivity, and for example, may be formed as a titanium thin film. However, a raw material of the external sealing member 173 is not limited to the above-described materials.

The external sealing member 173 may correspond to an outermost layer of a multilayer sealing structure so as to primarily accommodate a laser beam and may transfer laser melting heat to the interlayer sealing member 172 to be coupled to the first substrate 110 through the interlayer sealing member 172. However, according to the present embodiment, the external sealing member 173 may be transited to a melting state or a semi-melting state by laser irradiation and may be fused directly to the first substrate 110. For example, although the external sealing member 173, which primarily accommodates a laser beam, may maintain a substantially uniform thickness and substantially planar shape in spite of laser irradiation, the step portions 170a may be formed on two edge portions of the external sealing member 173 via, for example, a laser heating method and a pressing method.

The external sealing member 173 may have a wide width to cover the interlayer sealing member 172, thereby effectively prevent penetration of external impurities. An external surface of the external sealing member 173 may have step portions (or non-linear portion(s)) (which correspond to the step portions 170a) by using a laser irradiation method and a pressing method. In this case, the external sealing member 173 and the interlayer sealing member 172 may have a stepped interface therebetween. The stepped interface between the external sealing member 173 and the interlayer sealing member 172 may effectively shield from external impurities.

According to an embodiment, the inlet sealing member 170 may have the step portions 170a formed on two sides of the inlet sealing member 170. The cover member 171 corresponding to a lowermost layer of the inlet sealing member 170 may have a step structure formed on the first substrate 110. During laser-heating and pressurization of the external sealing member 173, the external sealing member 173 formed on the cover member 171 and the external sealing member 173 formed on the first substrate 110 may be stepped.

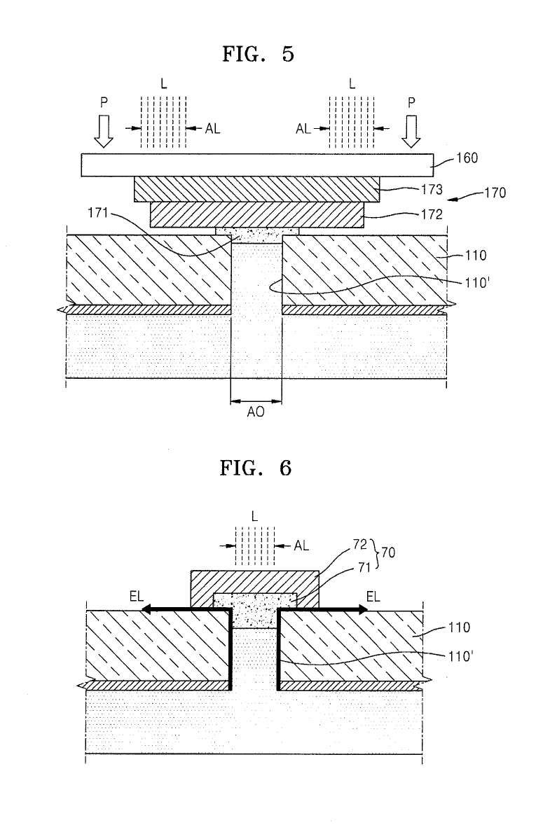

FIG. 5 is a cross-sectional view for describing a sealing operation of the electrolyte inlet 110′ shown in FIG. 4 according to an embodiment. Referring to FIG. 5, a pressurizing plate 160 may be positioned over the electrolyte inlet 110′ and the inlet sealing member 170 formed around the electrolyte inlet 110′ and a laser beam L may be irradiated while a predetermined pressure P is applied through the pressurizing plate 160 to press the inlet sealing member 170 on the first substrate 110. In another embodiment, other energy source such as thermal, electrical, light energy, which can fuse a sealing member to the first substrate 110, may be used instead of or in addition to the laser beam L. For the purpose of convenience, the laser irradiation will be described. By using the laser beam L to intensively provide a high energy density to the laser irradiation areas AL, a problem in terms of leakage of electrolyte due to excessive heat transferred to the electrolyte inlet 110′ may be overcome.

According to an embodiment, the laser irradiation areas AL may be set to substantially deviate from the electrolyte inlet 110′. That is, if the electrolyte inlet 110′ is viewed in a substantially vertical direction, for example, with respect to the first substrate 110, the laser irradiation areas AL may be set on two external sides that deviate from a viewing area AO of the electrolyte inlet 110′. In another embodiment, the laser irradiation areas AL do not overlap or are not aligned with an entrance of the electrolyte inlet 110′ in a direction along which the electrolyte inlet 110′ extends.

FIG. 6 is a cross-sectional view for describing a sealing structure of the electrolyte inlet 110′ according to a comparative example. Referring to FIG. 6, a cover member 71 is disposed to directly cover the electrolyte inlet 110′ and an external sealing member 72 is disposed on the cover member 71. The cover member 71 and the external sealing member 72 constitute a sealing member 70 for sealing the electrolyte inlet 110′.

In this case, if the laser beam L is irradiated on the cover member 71, which directly covers the electrolyte inlet 110′, that is, if the laser irradiation areas AL are formed on the electrolyte inlet 110′, laser heating is concentrated on the cover member 71 and thus the cover member 71 is excessively melted to deteriorate sealing properties of the electrolyte 150. Thus, the electrolyte 150 may leak through the cover member 71 or the electrolyte 150 may leak between the cover member 71 and the first substrate 110 (refer to a reference arrow EL). The electrolyte 150 may contaminate the first substrate 110, in particular, a fusing portion on the first substrate 110, if leaked, thereby hindering close attachment between the sealing member 70 and the first substrate 110.

The cover member 71 may prevent leakage of the electrolyte 150 while primarily shielding the electrolyte inlet 110′ and may prevent the fusing portion of the first substrate 110 from being contaminated. When the laser beam L is directly irradiated to the cover member 71, the cover member 71 having low thermal shape-stability may have excessive liquidity or may not maintain a substantially planar shape for covering the electrolyte inlet 110′. Thus, the electrolyte 150 may leak through the cover member 71 or the electrolyte 150 may leak along an interface between the cover member 71 and the first substrate 110, thereby contaminating the fusing portion of the first substrate 110 to which the sealing member 70 is fused.

As shown in FIG. 5, the laser irradiation areas AL are set to substantially deviate from the viewing area AO of the electrolyte inlet 110′. The interlayer sealing member 172 and the external sealing member 173 are sequentially stacked on the cover member 171 covering the electrolyte inlet 110′. Then, the pressurizing plate 160 is positioned over the external sealing member 173 and the laser beam L is applied to the laser irradiation areas AL substantially deviating from the viewing areas AO of the electrolyte inlet 110′ while the predetermined pressure P is applied so as to seal the inlet sealing member 170. Irradiation of the laser beam L and pressurization may be performed until the inlet sealing member 170 is stably fused onto the first substrate 110 formed around the electrolyte inlet 110′.

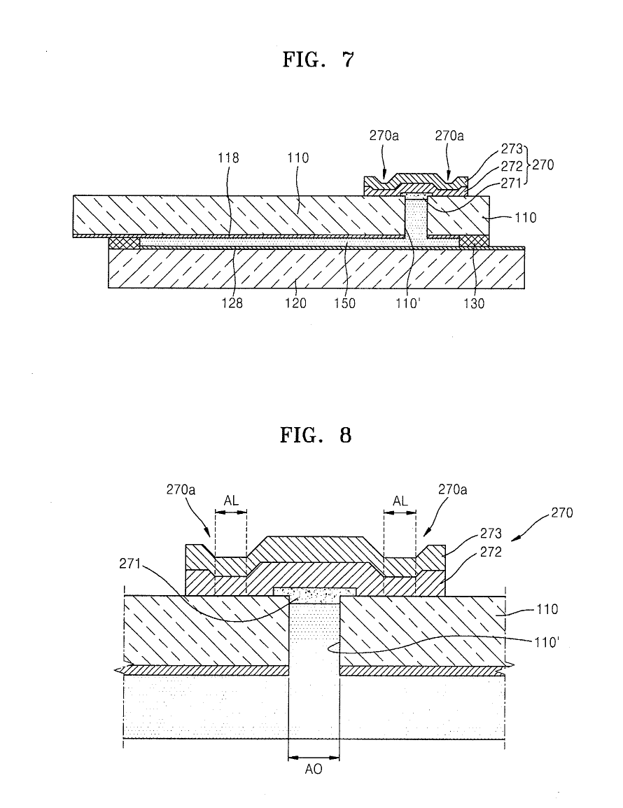

FIG. 7 is a cross-sectional view for describing a sealing structure of the electrolyte inlet 110′ according to another embodiment. FIG. 8 is an enlarged cross-sectional view of the sealing structure of FIG. 7 according to another embodiment of the present invention.

Referring to FIGS. 7 and 8, an inlet sealing member 270 may include i) a cover member 271 that directly covers the electrolyte inlet 110′, ii) an external sealing member 273 formed on the cover member 271 and corresponding to an outermost portion of the inlet sealing member 270, and iii) an interlayer sealing member 272 interposed between the cover member 271 and the external sealing member 273.

The external sealing member 273 may include right and left step portions 270a each having a concave shape. For example, the step portions 270a each having a concave shape may correspond to the laser irradiation areas AL (refer to FIG. 8), respectively.

The step portions 270a each having a concave shape may be formed by pressing the laser irradiation areas AL by a pressure that is amplified by a laser scribing material during laser-heating and pressurization. In more detail, during laser-heating and pressurization of the inlet sealing member 270, the laser scribing material is positioned on the external sealing member 273 and a laser beam is irradiated to the laser scribing material, thereby facilitating ignition of the laser scribing material. In addition, the laser irradiation areas AL are pressed downward by an ignition pressure to form the step portions 270a each having a concave shape. In this case, the laser scribing material may be, for example, a transparent conductive oxide (TCO) such as indium tin oxide (ITO), fluorine tin oxide (FTO), antimony tin oxide (ATO), or the like.

According to the present embodiment, during the laser irradiation and the pressurization, the inlet sealing member 270 formed around the electrolyte inlet 110′ is pressed onto the first substrate 110. The laser irradiation areas AL may constitute the step portions 270a, which are concavely pressed under a relatively high pressure according to the ignition of the laser scribing material.

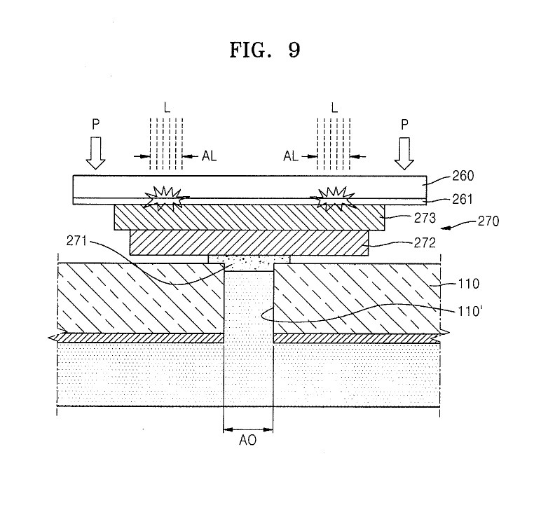

FIG. 9 is a cross-sectional view for describing a sealing operation of the electrolyte inlet 110′ shown in FIG. 8 according to another embodiment. Referring to FIG. 9, the cover member 271 is disposed on the electrolyte inlet 110′ and the interlayer sealing member 272 and the external sealing member 273 are sequentially stacked on the cover member 271. Furthermore, a pressurizing plate 260 having a surface coated with a laser scribing material 261 is positioned on the external sealing member 273, and the laser beam L is irradiated while applying a predetermined pressure P. In this case, the laser irradiation areas AL may be set to substantially deviate from the viewing area AO of the electrolyte inlet 110′. For example, the laser irradiation areas AL may be set on edge portions of the interlayer sealing member 272 and the external sealing member 273, which substantially deviate from the viewing area AO of the electrolyte inlet 110′.

When the laser beam L is irradiated directly to the viewing area AO of the electrolyte inlet 110′, the electrolyte 150 may leak through the cover member 271 or may leak along an interface between the cover member 271 and the first substrate 110 according to thermal softening and liquidity of the cover member 271. The electrolyte 150 may contaminate the fusing portion of the first substrate 110 if leaked, thereby hindering close attachment of the inlet sealing member 270.

According to an embodiment, problems that arise when the laser beam L is irradiated directly to the cover member 271 may be overcome. For example, before the interlayer sealing member 272 and the external sealing member 273 are fused to the first substrate 110, the fusing portion on the first substrate 110 may be prevented from being contaminated due to excessive melting of the cover member 271. However, this does not mean that the cover member 271 is not melted.

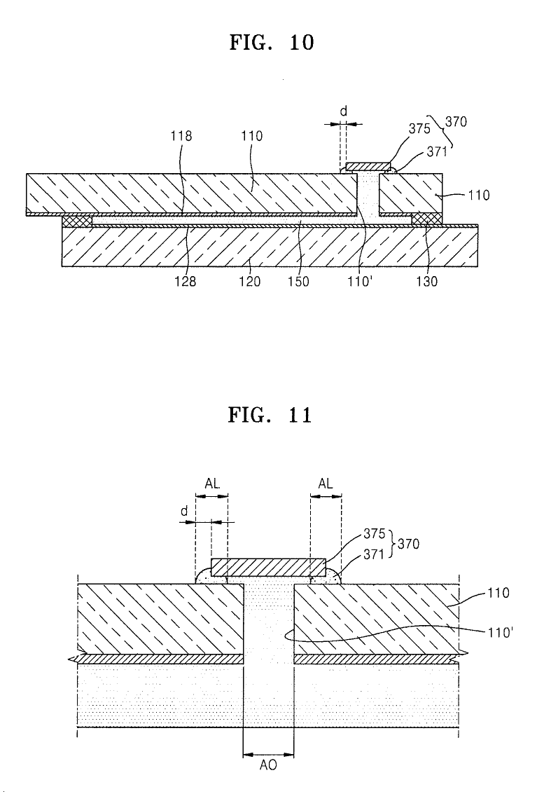

FIG. 10 is a cross-sectional view for describing a sealing structure of the electrolyte inlet 110′ according to another embodiment. FIG. 11 is an enlarged cross-sectional view of the sealing structure of FIG. 10, according to another embodiment.

Referring to FIGS. 10 and 11, an inlet sealing member 370 for sealing the electrolyte inlet 110′ includes an external sealing member 375 disposed on the electrolyte inlet 110′ and a glass frit 371 interposed between the external sealing member 375 and the first substrate 110. The external sealing member 375 covers the electrolyte inlet 110′ and extends to external regions that deviate from the viewing area AO of the electrolyte inlet 110′.

The external sealing member 375 is fused onto the first substrate 110, while the glass frit 371 is interposed between the external sealing member 375 and the first substrate 110. The glass frit 371 is formed to surround the electrolyte inlet 110′ and is fused between the first substrate 110 and the external sealing member 375 by laser irradiation. Thus, the external sealing member 375 is attached onto the first substrate 110. The glass frit 371 may surround the external sealing member 375 and may seal a space formed between the first substrate 110 and the external sealing member 375. The glass frit 371 may be formed to surround an end edge portion of the external sealing member 375 and may be formed to substantially deviate from the external sealing member 375 and to extend to right and left sides with respect to the viewing area AO of the electrolyte inlet 110′. For example, as shown in FIG. 11, the glass frit 371 may be formed outward from an end of the external sealing member 375 by a predetermined distance ‘d’. For example, the glass frit 371 may be formed to correspond to the laser irradiation areas AL to which a laser beam is irradiated.

The external sealing member 375 may be formed of a material having a thermal expansion coefficient substantially similar to the glass frit 371 and the first substrate 110. Since the photoelectric conversion device 100 operates at a temperature ranging from about 50° C. to about 80° C., there is a significant temperature difference between on and off of an operation of the photoelectric conversion device 100. In this case, when a difference in the thermal expansion coefficients between the external sealing member 375 and the glass frit 371, and a difference in the thermal expansion coefficients between the external sealing member 375 and the first substrate 110 are great, a thermal stress may be caused in a fusing portion of the external sealing member 375 and coupling of the external sealing member 375 may be mechanically damaged.

In one embodiment, the thermal expansion coefficients of the external sealing member 375, the first substrate 110, and the glass frit 371 are substantially similar. Thus, the first substrate 110 and the glass frit 371 may be formed of glass, and thus the thermal expansion coefficients of the external sealing member 375, the first substrate 110, and the glass frit 371 may be substantially similar to each other.

The external sealing member 375 may be formed of a material that has excellent fixation properties with the glass frit 371 and has a thermal expansion coefficient substantially similar to those of the glass frit 371 the first substrate 110. For example, the external sealing member 375 may be formed as a titanium thin film.

The external sealing member 375 is thermally fused onto the glass frit 371 by positioning the external sealing member 375 on the glass frit 371 coated around the electrolyte inlet 110′ and applying fusing heat to the resulting structure by laser irradiation. In this case, the laser irradiation may be applied from the glass frit 371 to the external sealing member 375. Since heat due to the laser irradiation may be transferred to the glass frit 371 through the external sealing member 375, the external sealing member 375 may be formed of a metal having excellent thermal conductivity, and for example, may be formed as a titanium thin film.

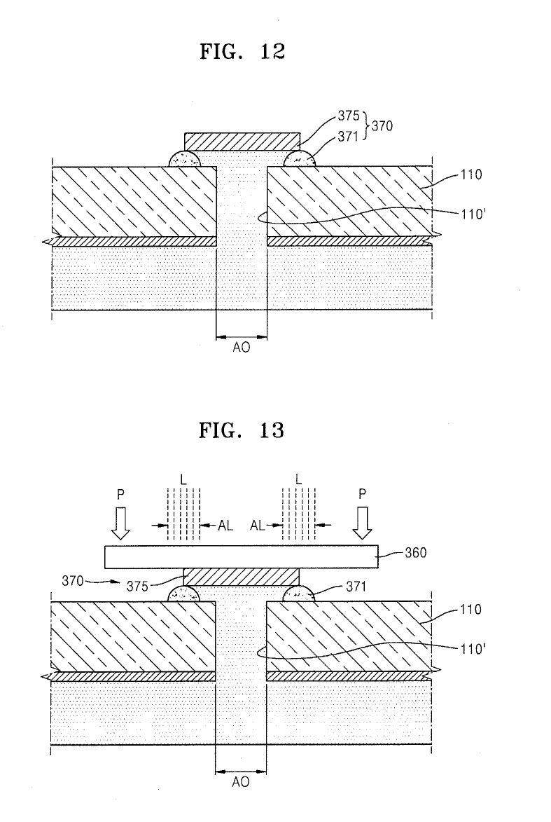

FIGS. 12 and 13 are cross-sectional views for describing a sealing operation of the electrolyte inlet 110′ shown in FIG. 11 according to another embodiment.

Referring to FIG. 12, the glass frit 371 is coated on a portion of the first substrate 110 around the electrolyte inlet 110′ and the external sealing member 375 is positioned on the glass frit 371. Then, as shown in FIG. 13, a pressurizing plate 360 may be positioned on the external sealing member 375 and a predetermined pressure P may be applied to the resulting structure. In this case, the predetermined pressure P is applied and substantially simultaneously the external sealing member 375 is fused onto the first substrate 110 by irradiating the laser beam L. The laser beam L may also be irradiated from the glass frit 371 to the external sealing member 375. By heat of the laser beam L directly applied to the glass frit 371 or heat of the laser beam L applied to the external sealing member 375, the glass frit 371 may be transited to a melting state or a semi-melting state and thus the external sealing member 375 may be fused onto the first substrate 110.

The laser irradiation areas AL may be set to extend to the right and left sides of the viewing area AO and to deviate from the viewing area AO obtained by viewing the electrolyte inlet 110′ in a substantially vertical direction, for example, with respect to the first substrate 110. In addition, the laser irradiation areas AL may correspond to a region on which the glass frit 371 is coated. The external sealing member 375 is pressed onto the first substrate 110 by irradiating the laser beam L and the glass frit 371 is pressed toward the right and left sides by pressing the pressurizing plate 360 so as to surround an end edge portion of the external sealing member 375, thereby sealing the electrolyte inlet 110′.

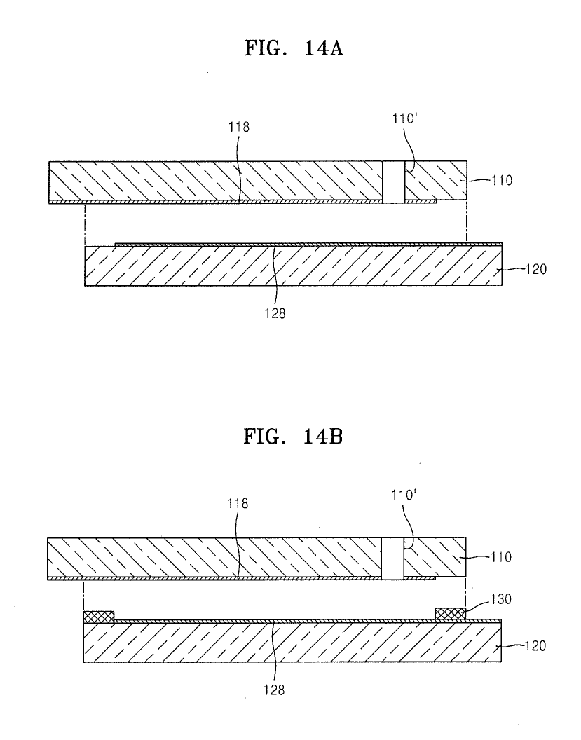

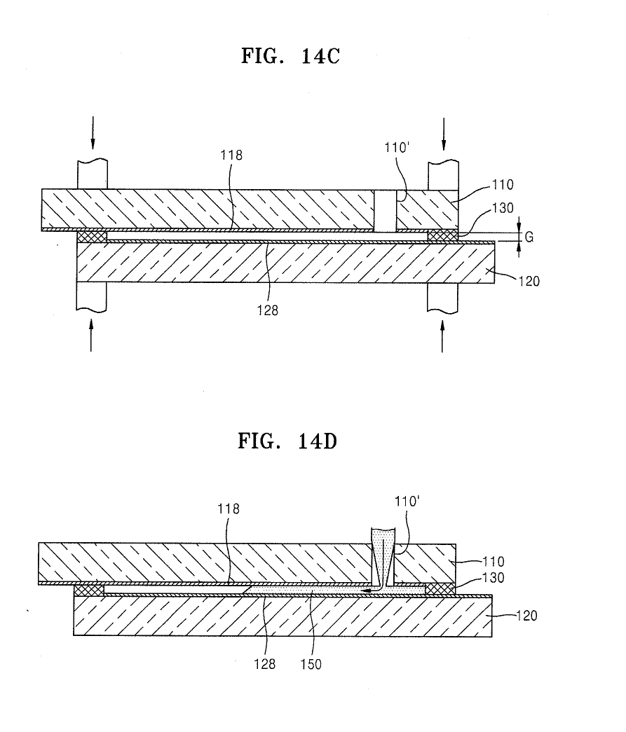

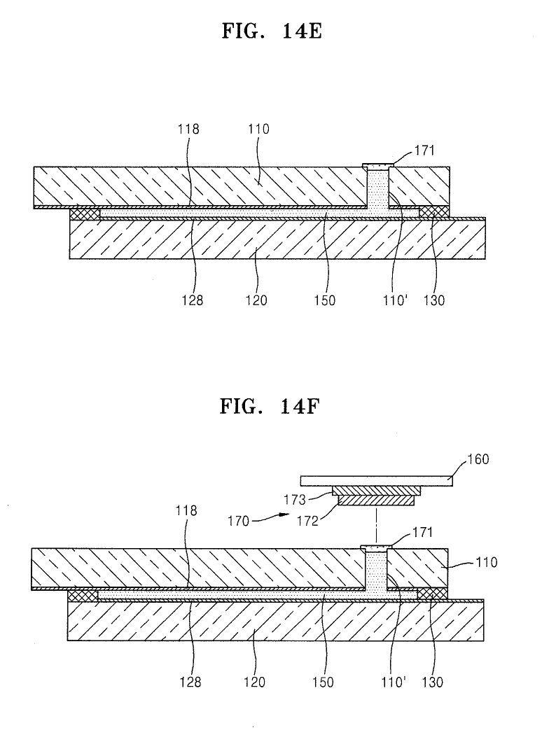

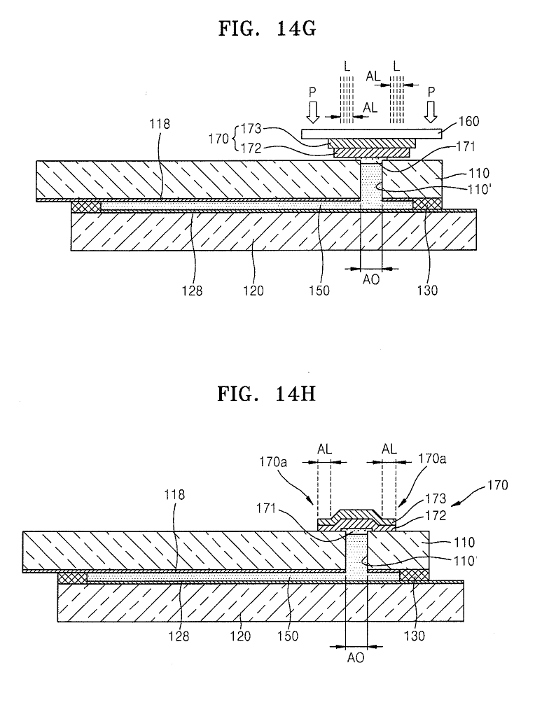

FIGS. 14A through 14H are cross-sectional views sequentially illustrating a method of manufacturing a photoelectric conversion device, according to an embodiment. First, the first and second substrates 110 and 120 on which the function layers 118 and 128 for performing photoelectric conversion are respectively formed are prepared (refer to FIG. 14A). At least one of the function layers 118 and 128 includes a semiconductor layer for generating electrons by being excited by irradiated light and electrodes for collecting and discharging the generated electrons. The electrolyte inlet 110′ for injecting an electrolyte is formed to pass through at least one of the first and second substrates 110 and 120. For example, the electrolyte inlet 110′ may be formed to pass through the first substrate 110.

Subsequently, the first and second substrates 110 and 120 are positioned to face each other, and the sealing member 130 is applied on the edges of the substrates 110 and 120 (refer to FIG. 14B). For example, a thermal fusion film as the sealing member 130 is disposed on the edges of the second substrate 120, and predetermined heat and pressure are applied thereto to attach the two substrates 110 and 120 to each other, thereby forming the substrate gap G into which the electrolyte 150 is to be injected (refer to FIG. 14C). Then, the electrolyte 150 is injected through the electrolyte inlet 110′ by applying an appropriate pressure and the electrolyte 150 is injected to be substantially filled in the substrate gap G (refer to FIG. 14D).

Then, the cover member 171 is positioned on the electrolyte inlet 110′ (refer to FIG. 14E). Since the cover member 171 primarily shields the electrolyte inlet 110′, before the inlet sealing member 170 including the interlayer sealing member 172 and the external sealing member 173 is fused onto the first substrate 110, the cover member 171 may prevent the electrolyte 150 from leaking and prevent the fusing portion of the first substrate 110 from being contaminated due to leaking of the electrolyte 150.

Then, the interlayer sealing member 172 and the external sealing member 173 are disposed over the electrolyte inlet 110′ and the cover member 171 formed around the electrolyte inlet 110′ and the pressurizing plate 160 is further disposed on the external sealing member 173 (refer to FIG. 14F).

Then, the inlet sealing member 170 is pressed onto a portion of the first substrate 110 around the electrolyte inlet 110′ while irradiating the laser beam L and applying a predetermined pressure P through the pressurizing plate 160 to the first substrate 110 (refer to FIG. 14G). By using the laser beam L to intensively provide a high energy density to the laser irradiation areas AL, a problem in terms of leakage of electrolyte due to excessive heat transferred onto the electrolyte inlet 110′ may be overcome. The laser irradiation areas AL may be set to substantially deviate from the electrolyte inlet 110′.

If the electrolyte inlet 110′ is viewed in a substantially vertical direction, for example, with respect to the first substrate 110, the laser irradiation areas AL may be set on two external sides that deviate from the viewing area AO of the electrolyte inlet 110′. Through the above-described operations, the inlet sealing member 170 including the step portions 170a formed on two edge portions thereof may be formed, as shown in FIG. 14H.

As described above, at least one of the disclosed embodiments provides a photoelectric conversion device with high sealing performance of an electrolyte inlet. In at least one of the disclosed embodiments, laser irradiation areas are set to substantially deviate from an electrolyte inlet, and thus the sealing properties of a cover member that primarily shield an electrolyte inlet may be maintained and an electrolyte may be prevented from leaking. Thus, a thermal fusing portion of an inlet sealing member may be prevented from being contaminated by leaking of the electrolyte and the inlet sealing member may be fixedly fused.

It should be understood that the above embodiments described herein should be considered in a descriptive sense only and not for purposes of limitation. Descriptions of features or aspects within each embodiment should typically be considered as available for other similar features or aspects in other embodiments.

What is claimed is:

1. A photoelectric conversion device configured to contain an electrolyte, the device comprising:
first and second substrates facing each other, wherein first and second electrodes are formed on the first and second substrates, respectively;
an electrolyte inlet formed to pass through at least one of the first and second substrates; and
a sealing member formed on an external surface of the first substrate to cover an entrance of the electrolyte inlet, wherein the sealing member comprises i) an inner area which is located substantially directly above the entrance of the electrolyte inlet and ii) at least one energy application area onto which energy is directly or indirectly applied, and wherein the energy application area extends outwardly from the inner area so as not to overlap with the entrance of the electrolyte inlet.

2. The photoelectric conversion device of claim 1, wherein the energy application area has at least one non-linear portion.

3. The photoelectric conversion device of claim 2, wherein at least part of the non-linear portion extends in an inclined direction toward the first substrate.

4. The photoelectric conversion device of claim 2, wherein the non-linear portion is concave toward the first substrate.

5. The photoelectric conversion device of claim 1, wherein the sealing member comprises:
a cover member configured to cover the entrance of the electrolyte inlet;
an interlayer sealing member disposed on the cover member; and
an external sealing member disposed on the interlayer sealing member.

6. The photoelectric conversion device of claim 5, wherein each of the cover member and the interlayer sealing member is formed of a hot-melt resin, and wherein the external sealing member is formed of a metal-based material.

7. The photoelectric conversion device of claim 5, wherein the external sealing member comprises a titanium thin film.

8. The photoelectric conversion device of claim 1, wherein the sealing member comprises:
a glass frit formed to surround the electrolyte inlet on the portion of the first substrate around the electrolyte inlet; and
an external sealing member formed on the glass frit.

9. The photoelectric conversion device of claim 8, wherein the energy application area is located substantially directly above the glass frit.

10. The photoelectric conversion device of claim 8, wherein the external sealing member comprises a titanium thin film.

11. The photoelectric conversion device of claim 1, wherein the energy application area is configured to receive a laser beam so as to fuse the sealing member onto the first substrate.

12. A photoelectric conversion device configured to contain an electrolyte, the device comprising:
first and second substrates facing each other, wherein first and second electrodes are formed on the first and second substrates, respectively;
an electrolyte inlet formed to pass through at least one of the first and second substrates; and
a sealing member formed on an external surface of the first substrate so as to surround an entrance of the electrolyte inlet, wherein the sealing member has a non-linear portion at least part of which extends in an inclined direction, and wherein the non-linear portion of the sealing member is not aligned with the entrance of the electrolyte inlet in a direction in which the electrolyte inlet extends.

13. The photoelectric conversion device of claim 12, wherein at least part of the non-linear portion is concave toward the first substrate.

14. The photoelectric conversion device of claim 12, wherein the non-linear portion is configured to receive a laser beam so as to fuse the sealing member onto the first substrate.

15. The photoelectric conversion device of claim 12, wherein the non-linear portion is not located directly above the entrance of the electrolyte inlet.

16. A photoelectric conversion device configured to contain an electrolyte, the device comprising:
first and second substrates facing each other, wherein first and second electrodes are formed on the first and second substrates, respectively;
an electrolyte inlet formed to pass through at least one of the first and second substrates; and
a sealing member formed on an external surface of the at least one substrate via a glass frit so as to surround an entrance of the electrolyte inlet.

17. The photoelectric conversion device of claim 16, wherein the glass frit does not overlap with the electrolyte inlet.

18. The photoelectric conversion device of claim 16, wherein the glass frit extends outwardly from the entrance of the electrode inlet beyond the perimeter of the sealing member.

19. The photoelectric conversion device of claim 16, wherein the sealing member comprises a titanium thin film.

20. The photoelectric conversion device of claim 16, wherein the sealing member does not directly contact the external surface of the at least one substrate.
